(19) United States
(12) Patent Application Publication
(10) Pub. No.: US 2008/0299718 A1
(43) Pub. Date: Dec. 4, 2008

(54) DAMASCENE PROCESS HAVING RETAINED CAPPING LAYER THROUGH METALLIZATION FOR PROTECTING LOW-K DIELECTRICS

(75) Inventors: Ping Jiang, Plano, TX (US); Deepak A. Ramappa, Dallas, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/757,147

(22) Filed: Jun. 1, 2007

(51) Int. Cl. H01L 21/336; H01L 21/4763

(52) U.S. Cl. 438/197; 438/626; 257/E21.577; 257/E21.409

(57) ABSTRACT

A method of forming single or dual damascene interconnect structures using either a via-first or trench first approach includes the steps of providing a substrate surface having an etch-stop layer thereon, a low-k dielectric layer on the etch-stop layer, and a dielectric capping layer on the low-k dielectric layer. In the single damascene process using trench pattern, a trench is etched through the capping layer, the low-k dielectric layer and the etch-stop layer to reach the substrate surface. In the via-first process, using a via pattern, the via is etched through the capping layer, the low-k dielectric layer and the etch-stop layer to reach the substrate surface. In the trench first process, using the via pattern the via is etched through the capping layer, the low-k dielectric layer and the etch-stop layer to reach the substrate surface. In the single damascene or either via-first or trench-first dual damascene embodiment, the capping layer is retained over the low-k dielectric layer on top surfaces of the trench into the metal processing, generally including CMP processing, wherein the CMP process removes at least a portion, and in one embodiment the entire, capping layer.

### FIELD OF THE INVENTION

The present invention relates to damascene processing for integrated circuits and integrated circuits therefrom.

### BACKGROUND OF THE INVENTION

Interconnect delay is known to be a major limiting factor in the drive to improve the speed and performance of integrated circuits (IC). One way to minimize interconnect delay is to reduce interconnect capacitance by using low dielectric constant (low-k) materials during production of the IC. In recent years, low-k materials have been developed to replace relatively high dielectric constant insulating materials, such as silicon dioxide. Specifically, low-k dielectrics having a k value significantly less than that of silicon dioxide, which has a k value of about 3.9, are needed. Unless otherwise noted, all k values mentioned in the present application are measured relative to a vacuum.

In particular, low-k films are being utilized for inter-level and intra-level dielectric layers between metal layers of semiconductor devices. Additionally, in order to further reduce the dielectric constant of insulating materials, material films may be formed with pores, commonly referred to as porous low-k dielectric films. Available low-k films which provide a k≦2.6 are generally referred to as ultra low-k (ULK) films. Such low-k films can be deposited by a spin-on dielectric (SOD) method similar to the application of photoresist, or by chemical vapor deposition (CVD). Thus, the use of low-k materials is readily adaptable to existing semiconductor manufacturing processes.

In certain damascene processes, a capping layer is applied during damascene processing to the low-k dielectric layer, such as a tetra-ethyl-ortho-silicate (TEOS) cap. The capping layer is used as a sacrificial layer to protect ULK film during via and trench patterning, and in the event of resist rework processing. In the exemplary dual damascene process described below, which is not part of the present invention and only used for contrast to the present invention, the TEOS cap is removed completely during the trench etch-stop etch.

The exemplary known via-first dual damascene process proceeds as follows. In FIG. 1(a), layers 4 and 12 represent the Front-End-Of-Line (FEOL) transistor layer and a single damascene layer 12, respectively. On top of single damascene layer 12, etch-stop deposition, ULK deposition, and then TEOS deposition occurs. The cross sectional stack shown in FIG. 1(a) shows TEOS layer 29, on ULK layer 19, which is on etch-stop layer 20. The thickness of TEOS layer 29 is generally at least 600 A. The TEOS thickness is set to be thick enough to limit etching of the top surface of the ULK layer during the etch-stop layer etch described below, where a nominal etch-stop layer thickness is 600 A, and the etch rate of the etch-stop layer (such as SiC) is typically less as (compared to the TEOS cap. A lithography process including a via mask, photoresist 111 and BARC layer 112 is then performed on the structure shown in FIG. 1(b) to pro vide the via pattern 116 shown. Using the via pattern, and a highly non-isotropic etch, a via is formed through capping layer 29, and low-k dielectric layer 19, while preserving etch-stop layer 20, to result in the structure shown in FIG. 1(c). Photoresist 111 and BARC 112 are then removed, such as by ashing. The via (wafer) is then cleaned to remove residuals in a via clean step. A trench pattern 115 is then applied, such as using light sensitive photoresist 121 and BARC 122 as shown in FIG. 2(d). A trench is then formed using a highly non-isotropic trench etch through the capping layer 29 and a potion of the low-k dielectric layer 19 to reach a predetermined trench depth, with the resulting structure as shown in FIG. 1(e). The photoresist 112 and BARC 122 are then asked, followed by a clean. The etch-stop layer 20 is then etched. During the etch-stop etch, the capping layer 29 is generally removed completely from the wafer to result in the structure shown in FIG. 1(g). FIG. 1(h) shows a cross section view of the resulting structure after barrier, seed and metal (e.g. Cu) filling (barrier and seed layer not shown). Note the absence of the capping layer 29 beneath the metal 31 on the top surfaces of the trench. FIG. 1(i) shows a cross section view of the resulting structure after chemical-mechanical polishing (CMP) processing.

While low-k materials are promising for fabrication of semiconductor circuits, these films also provide many challenges. First, low-k films tend to be less robust than more traditional dielectric layers and can be damaged during certain wafer processing steps, such as by etch and plasma ashing processes generally used in patterning the dielectric layer as described above, as well as from barrier/seed deposition processes and CMP. Further, some low-k films tend to be highly reactive when damaged, particularly after patterning, thereby allowing the low-k material to absorb water and/or react with other vapors and/or process contaminants that can alter the electrical properties of the dielectric layer. As a result, the low-k material, originally having a low dielectric constant, can suffer damage leading to an increase in its dielectric constant and resulting capacitance and other detrimental effects that result in a loss of some of its initially intended benefits.

### SUMMARY

The present invention involves an etch process which etches the etch-stop layer(s) (e.g. SiCN/SiCO) during trench etch for single damascene and via etch for dual damascene, so that the capping layer (e.g. TEOS) thickness as deposited is retained on the top surfaces of the trench to reach metallization processing. The retained capping layer protects low-k films for modern process flows having a single damascene for metal-1 and/or one or more dual damascene steps, and has been found to provide improved topography, improved dimensional control, and better electrical performance. As defined herein, a low-k dielectric material has a dielectric constant of 2.6-3.0, while a low-k dielectric is a ULK material which is defined herein to have a dielectric constant of <2.6.

A via-first method of forming dual damascene interconnect structures comprises the steps of providing a substrate surface having an etch-stop layer thereon, a low-k dielectric layer on the etch-stop layer, and a dielectric capping layer on the low-k layer. A via pattern is formed using a via mask and at least one layer of light sensitive material. Using the via pattern, at least one via is etched, wherein the via is etched through the capping layer, the low-k dielectric layer and the etch-stop layer to reach the substrate surface. A trench pattern is provided over the via using a trench mask and at least one layer of light sensitive material. At least one trench is etched using the trench pattern, wherein the trench is etched through the capping layer and a portion of the low-k dielectric layer to reach a predetermined trench depth. The capping layer continues to be retained over the low-k dielectric layer on the top surfaces of the trench. The trench and via are then filled with at least one electrically conductive material, for example copper.

A trench-first method of forming dual damascene interconnect structures comprises the steps of providing a substrate surface having an etch-stop layer thereon, a low-k dielectric layer on the etch-stop layer, and a dielectric capping layer on the low-k dielectric layer, forming a trench pattern using a trench mask and at least one layer of light sensitive material, and etching at least one trench using the trench pattern. The trench is etched through the capping layer, a portion of the low-k dielectric layer to reach a predetermined trench depth, wherein the capping layer is retained over the low-k dielectric layer on the top surfaces of the trench. A via pattern is provided over the trench using a via mask and at least one layer of light sensitive material, and using the via pattern at least one via is etched through the capping layer, the low-k dielectric layer and the etch-stop layer to reach the substrate surface. The capping layer continues to be retained over the low-k dielectric layer on the top surfaces of the trench. The via and trench are then filled with at least one an electrically conductive material to form a dual damascene interconnect structure.

In either the via-first or trench first processes, a chemical-mechanical polishing (CMP) is generally performed to remove excess conductive material (such as copper) and at least a portion of the capping layer from the surface of the low-k dielectric to form a dual damascene interconnect structure. The capping layer can comprise TEOS, silicon carbide, silicon nitride or silicon oxy-nitride. In one embodiment, the thickness of the capping layer is between 100 and 500 A. The filling step can comprises the steps of depositing a barrier layer to line the via and the trench, depositing a seed layer on the barrier layer, and depositing a Cu comprising metal on the seed layer. The CMP step can remove a portion or all of the capping layer. The etch-stop layer can comprise SiCN, SiCO/SiCN, Si₃N₄ or SiCO/Si₃N₄. The low-k dielectric layer can be deposited as a CVD film or a spin-on film. The method can further comprise the steps of providing a semiconductor substrate, prior to forming the dual damascene interconnect structure, forming at least one MOS transistor in and on the substrate, the MOS transistor comprising a source and drain having a channel region interposed between, and a gate electrode and a gate insulator over the channel region, and a layer of dielectric insulation including at least one metal contact electrically coupled to the transistor, wherein the dual damascene interconnect structure is electrically coupled to the metal contact.

A method of forming single damascene interconnect structures comprises the steps of providing a substrate surface having an etch-stop layer thereon, a low-k dielectric layer on the etch-stop layer, and a dielectric capping layer on the low-k dielectric layer. A trench pattern is formed using a trench mask and at least one layer of light sensitive material, then using the trench pattern, the trench is etched through the capping layer, the low-k dielectric layer and the etch-stop layer to reach the substrate surface, wherein the capping layer is retained over the low-k dielectric layer on the top surfaces of the trench. The trench is then filled with at least one an electrically conductive material to form a single damascene interconnect structure. The capping layer can comprise TEOS, a silicon carbide, a silicon nitride or a silicon oxy-nitride. The thickness of the capping layer can be between 100 and 500 A, and the filling step can comprise depositing a barrier layer to line the trench, depositing a seed layer on the barrier layer, and depositing a Cu comprising metal on the seed layer. The method can further comprise the step of chemical mechanical polishing (CMP), wherein the CMP step can remove a portion of, or remove all of, the capping layer. The etch-stop layer can comprise SiCN, SiCO/SiCN, Si₃N₄ or SiCO/Si₃N₄ and the low-k dielectric layer can be deposited as a CVD film or a spin-on film. The single damascene method can further comprise the steps of providing a semiconductor substrate, prior to forming the damascene interconnect structure, forming at least one MOS transistor in and on the substrate, the MOS transistor comprising a source and drain having a channel region interposed between, and a gate electrode and a gate insulator over the channel region, a layer of dielectric insulation including at least one metal contact electrically coupled to the transistor, wherein the single damascene interconnect structure is electrically coupled to the metal contact.

### BRIEF DESCRIPTION OF THE DRAWINGS

FIGS. 1(a)-(i) are cross sectional views of intermediate steps in a known via-first dual damascene process.

FIG. 2(a) is a cross-section view of a completed semiconductor wafer fabricated in accordance with a first embodiment of the present invention.

FIG. 2(b) is a cross-section view of a completed semiconductor wafer fabricated in accordance with another embodiment of the present invention.

FIGS. 3(a)-(h) are cross sectional views of intermediate steps in an exemplary via-first dual damascene process according to the present invention.

FIG. 4(a) is a scanning electron microscopy (SEM) image showing topography achieved using a conventional via-first dual damascene process (ULK without a capping layer), while FIG. 4(b) is a SEM image showing topography achieved using a via-first dual damascene process according to the present invention (ULK with a 200 A TEOS capping layer). These images were both taken after trench-2 etch clean that is, right before metal-2 barrier/seed deposition). The thick white edges in FIG. 4(a) evidence a high degree of undesirable trench corner rounding (or erosion). The white edges in FIG. 4(b) are significantly thinner. In addition, the trench line-edge-roughness (LER) is also seen to be much more severe in the image shown in FIG. 4(a) as compared to the trench LER in the image based on dual damascene processing according to the present invention shown in FIG. 4(b).

FIGS. 5(a) and (b) show traced contour representations of SEM-derived trench cross-section images for a conventional TEOS cap removal process after the trench etch process as compared to a trench process according to the invention where the TEOS (or other) capping layer is retained over the top surfaces of the trench at least through CMP processing, respectively. The solid line in each representation is derived from a SEM taken after trench etch, and the dashed line is derived from a SEM of the same structure following a dilute HF (50:1 or 100:1) dip for 20 to 30 sections which quickly and preferentially removes the process damaged ULK.

FIG. 6 shows a plot of line-to-ground capacitance for capacitors formed using the conventional process via process described above which removes the capping layer at etch-stop etch, as compared to capacitors formed using the process according to the invention which retains the capping layer (e.g. TEOS) over the top surfaces of the trench through at least CMP processing.

### DETAILED DESCRIPTION OF THE INVENTION

The present invention is described with reference to the attached figures, wherein like reference numerals are used throughout the figures to designate similar or equivalent elements. The figures are not drawn to scale and they are provided merely to illustrate the instant invention. Several aspects of the invention are described below with reference to example applications for illustration. It should be understood that numerous specific details, relationships, and methods are set forth to provide a full understanding of the invention. One having ordinary skill in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

Particularly with the introduction of ULK films to the Back-End-Of-Line (BEOL) flow in modern semiconductor processes, such as for 45 nm technology, plasma etch and ash damage is substantially worsened, resulting in a significant increase in the k value, as well as undesirable trench line-edge-roughness (LER) for the ULK. The ULK damage is generally more severe at the top surfaces of trenches and vias. LER can lead to metal shorts and reliability failure. Conventional barrier/seed metal deposition processes also tend to make trench corner rounding worse.

The solution to the above problems with low-k films for modern process flows having a single damascene for metal-1 and/or one or more dual damascene steps developed by the present Inventors involves etching the etch-stop layer(s) (e.g. SiCN/SiCO) during trench etch for single damascene and via etch for dual damascene, so that the capping layer (e.g. TEOS) thickness as deposited is retained on the top surfaces of the trench. The capping layer protects the low-k film at the top surfaces of the trench during trench ash, trench clean, barrier/seed deposition, and the first part of the CMP process. The present invention is especially useful for ULK integration.

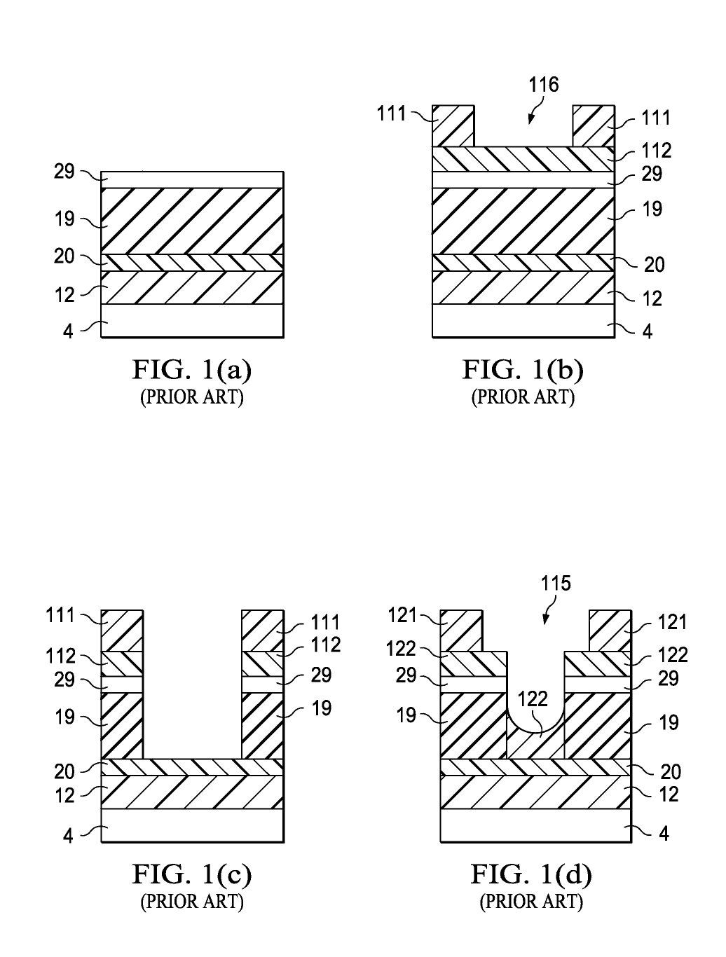

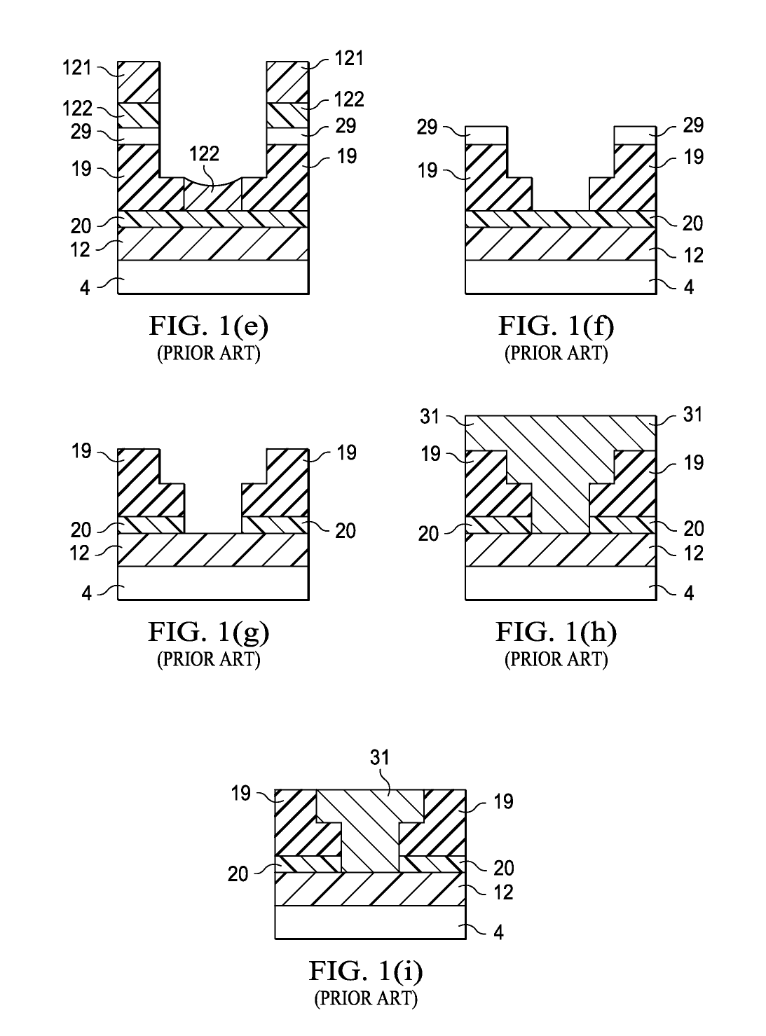

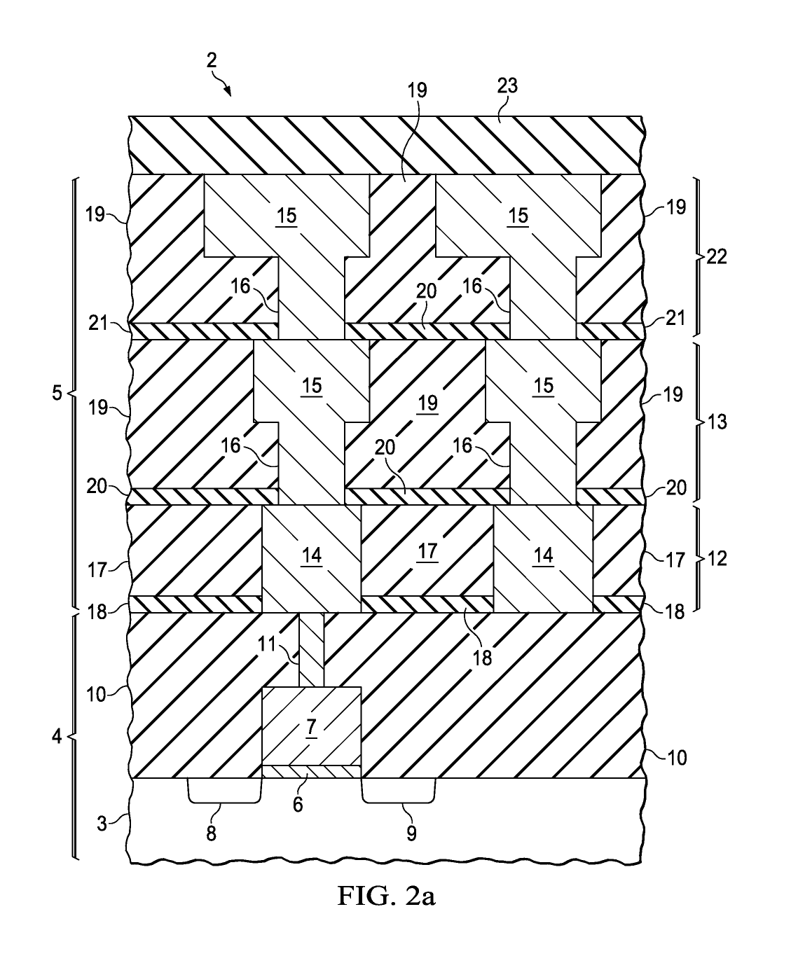

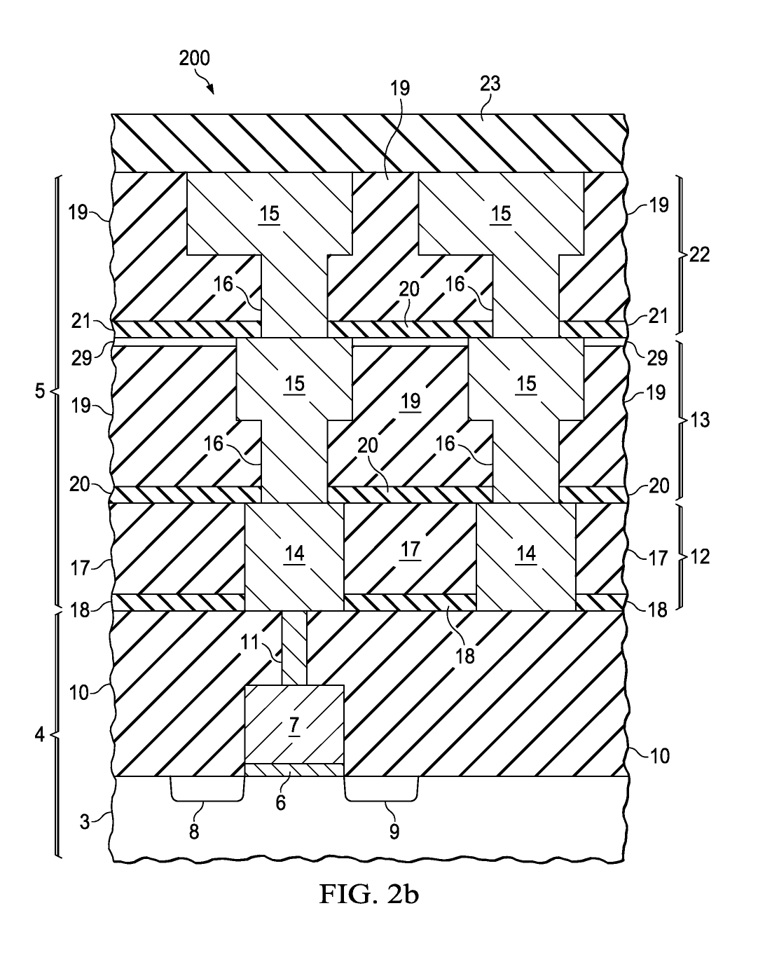

Now referring to the drawings, FIG. 2(a) is a cross-section view of a completed semiconductor wafer 2 fabricated in accordance with a first embodiment of the present invention. Generally, the fabrication of an integrated circuit is divided into two parts: the fabrication of the Front-End-Of-Line (FEOL) structure 4 and the fabrication of the BEOL structure 5. The structure that includes the silicon substrate 3 is called the FEOL structure 4 of the integrated circuit. Normally, the FEOL 4 is the transistor layer formed on (and within) the semiconductor substrate 3. The semiconductor substrate 3 is preferably a doped single-crystal silicon substrate. However, other semiconductors substrates, such as, but not limited to, GaAs and InP may be used. The partial FEOL 4 shown in FIG. 1 includes a transistor having a gate oxide 6, a gate electrode 7, and source/drain 8, 9; however, it is within the scope of the invention to have a plurality of transistors and other circuit components interconnected to realize any form or function including other logic elements within the FEOL structure 4.

Immediately above the transistor shown is a layer of dielectric insulation 10 containing metal contacts 11 that electrically tie the transistor to the other logic or other circuit elements (not shown) of the FEOL structure 4. The dielectric insulation 10 may be comprised of any suitable materials such as SiO₂, organo-silicate glass (OSG), fluorinated silica glass (FSG), phosphate-doped silica glass (PSG), or any other suitable dielectric material. The contacts 11 are preferably comprised of W; however other electrically conductive materials such as Cu, Ti, or Al may be used. An optional dielectric liner (not shown) may be formed before the dielectric insulation layer 10. If used, the dielectric liner may be any suitable material, such as silicon nitride. Similarly, an optional contact liner (not shown) may be formed before the placement of the contacts 11 to reduce the contact resistance at the interface between the contact 11 and the active devices within the FEOL structure 4 (i.e. the gate electrode 11). If used, the contact liner may be any suitable material, such as Ti, TiN, or Ta.

The example BEOL 5 contains a single damascene layer 12 and at least one dual damascene layer, shown as a first dual damascene layer 13 and a second dual damascene layer 22. Layers 12, 13 and 22 contain metal lines 14, 15 that properly route electrical signals and power properly through the electronic device. Layers 13 and 22 also contain vias 16 that properly connect the metal lines of one metal layer (e.g. the metal lines 14 of layer 12) to the metal lines of another metal layer (e.g. the metal lines 15 of layer 13).

The single damascene layer 12 has metal lines 14 electrically insulated by dielectric material 17. The metal lines 14 may contain any electrically conductive material such as Cu. However, the use of other materials such as Al, Ti, Ag, Sn, or Au, or alloys thereof, are within the scope of this invention. In accordance with one embodiment of the invention, the dielectric material 17 is a low-k material such as OSG. However, the dielectric material 17 may also be FSG, SiO₂, any other low-k material, or any ULK material. Furthermore, the single damascene layer 12 may have a thin dielectric layer 18 formed between the dielectric material 17 and the FEOL 4. Preferably, the thin dielectric layer 18 is comprised of SiCN; however, it is within the scope of this invention to use any suitable material for the thin dielectric layer 18. For example, the thin dielectric layer 18 may comprise SiC, SiCO, SiON, or Si₃N₄.

The thin dielectric layer 18 may perform many functions. For example, dielectric layer 18 may function as a diffusion barrier layer by preventing the copper or other metals from interconnects 14 from diffusing to the silicon channel of the transistor or to another isolated metal line (thereby creating an electrical short). Second, thin dielectric layer 18 may function as an etch-stop when manufacturing the metal lines 14 within the dielectric insulation material 17. Moreover, the thin dielectric layer 18 may function as an adhesion layer to help hold a layer of OSG 17 to the FEOL 4. For purposes of readability, the thin dielectric layer 18 will be called the etch-stop layer 18 during the rest of the description of this invention.

Dual damascene layers 13 and 22 contain metal lines 15 and vias 16 that are electrically insulated by dielectric material 19. No capping layer (e.g. TEOS) is shown on dielectric layer 19. However, as described below relative to FIG. 2(b), a portion of the capping layer used to protect the low-k dielectric can be retained over dielectric layer 19 in the completed wafer. The metal lines 15 may contain any metal such as Cu. However, the use of other metals such as Al, Ti, Ag, Sn, or Au, as well as alloys is within the scope of this invention. In accordance with one embodiment of the invention, the dielectric material 19 is a low-k material such as OSG. However, the dielectric material 19 may also be FSG, SiO₂, any other low-k material, or any ULK material.

The dual damascene layers 13 and 22 also contain dielectric etch-stop layers 20 and 21, respectively, that serve as a via etch-stop layer during manufacturing. Preferably, the etch-stop layers 20 and 21 are both SiCN, but any suitable dielectric material such as SiC, SiCO, SiON, or Si₃N₄ may be used as the etch-stop layer 20 and 21. Bi-layer etch-stops can also be used, such as SiCO on SiCN, SiCO on Si₃N₄.

A protective passivation overcoat 23 shown in FIG. 2(a) is usually formed over the last interconnect layer 22 to provide an environmental barrier, such as to oxygen and moisture. Any suitable material may be used for the protective overcoat 23, such as SiO₂ or SiN, or a combination thereof.

FIG. 2(b) is a cross-section view of a completed semiconductor wafer 200 fabricated in accordance with another embodiment of the present invention. Semiconductor wafer 200 includes a residual portion of capping layer 29 in dual damascene layers 13 that is described as being removed entirely from semiconductor wafer 2 during CMP processing. The thickness of capping layer shown in FIG. 2(b) is as thin as possible, such as 20 A to 200 A, to provide protection to the low-k dielectric yet limit the associated increase in capacitance that results from the presence of the high dielectric constant capping layer (e.g. TEOS) relative to the low-k dielectric. Although not shown, capping layer 29 can be provided in the other damascene layers in the completed wafer.

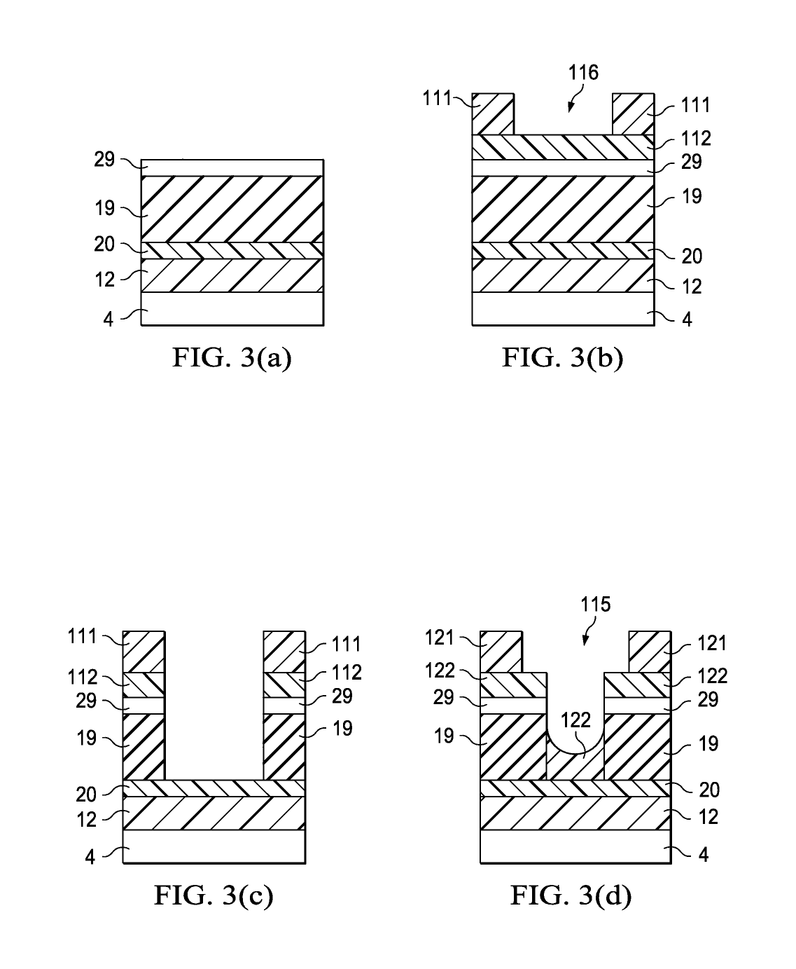

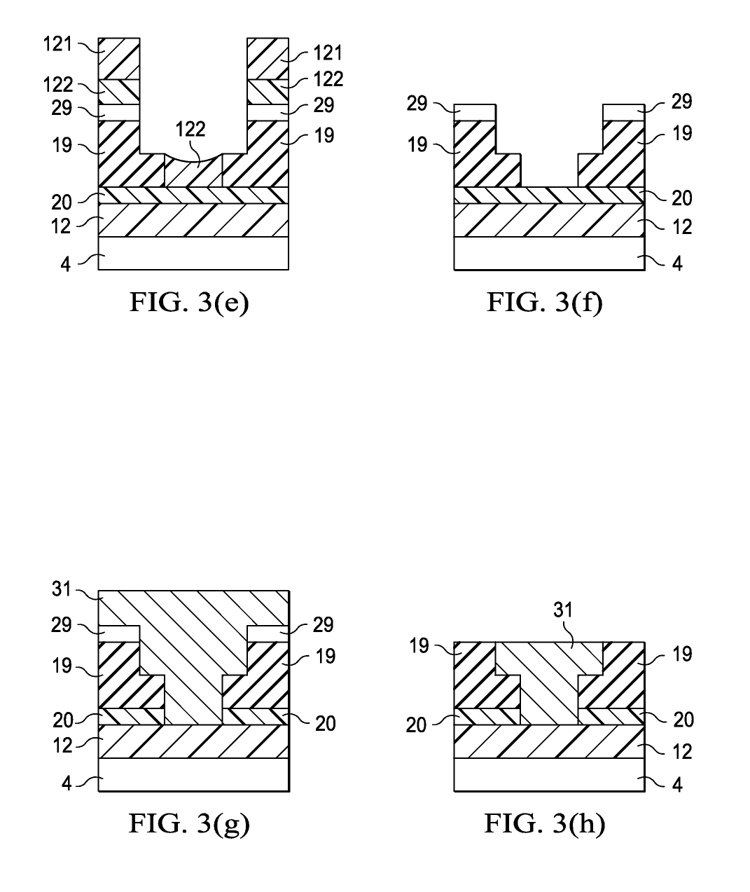

FIGS. 3(a)-(h) provide cross section views of intermediate steps in an exemplary via-first dual damascene process according to the present invention. FIG. 3(a) shows a view of a capping layer 29, on a low-k dielectric layer 19, on an etch-stop layer 20, which can all be deposited serially. Capping layer 29 is compositionally different as compared to low-k dielectric layer 19. Capping layer 29 may be any suitable material, such as TEOS. TEOS has a k-value of about 4.2. The TEOS used is generally undoped TEOS. Doped TEOS can also be used. Although capping layer 29 will generally be described herein as being a TEOS layer, it is understood that a variety of other materials including, but not limited to, silicon carbide, silicon nitride and silicon oxy-nitride can also be used as capping layer 29.

The thickness of the as-deposited capping layer 29 is <600 A, and is generally in the range of from 100 to 500 A, such as 150 A, 200 A, 250 A, 300 A, 350 A, 400 A or 450 A. The TEOS cap is preferably as thin as possible within the margin provided by the process used. TEOS being denser than the low-k dielectric will give good etch selectivity with the low-k dielectric. Via and trench undercutting needs to be minimized to help metal fill (Barrier, Seed, and ECD). If the TEOS cap is thicker, such as 100 A to 1000 A, or more, the undercut has been found to be more severe as there will be more lateral etching of the low-k material. Further, as the TEOS cap thickness increases, CMP processing becomes more complicated. A preferred TEOS cap thickness is <150 A so as to use the thinnest practical TEOS thickness, with the minimum thickness generally limited by the TEOS cap thickness control margin across a wafer.

As described below, capping layer 29 is a sacrificial layer that is preferably completely removed during CMP due to the resulting effective k value increase if not removed. However, the present invention provides the option of leaving at least a portion of the capping layer 29 in the final device, as described above relative to FIG. 2(b).

Etch-stop layer 20 is on damascene layer, such as damascene layer 12, which is on FEOL 4 as shown in FIGS. 2(a) and (b). A via pattern 116 is applied to capping layer 29 as shown in FIG. 3(b), such as using known lithographic techniques with light sensitive photoresist 111 and bottom anti-reflective coating (BARC) 112. Although shown as a single layer resist scheme, the invention can be practiced with multi-layer schemes, including bi-layer and tri-layer resist schemes for via and/or trench patterning. Using the via pattern, and a highly non-isotropic etch, a via is formed through capping layer 29, low-k dielectric layer 19 and etch-stop layer 20 to result in the structure shown in FIG. 3(c).

Known industry standard etch conditions can be used for etching capping layer 29 and low-k dielectric layer 19. Regarding the etching etch-stop layer 20, an exemplary process is provided below. A suitable etcher is a Tokyo Electron Ltd (TEL) SCCM Etcher. Other RIE etchers can be also used. Exemplary etch conditions comprise a 20 C chuck temperature, pressure of 50 mTorr, 1000 Watt source power, 200 Watt bias power, and 100 sccm of CF₄ gas. Process parameters may be varied.

Since the etch-stop etch is performed right after via etch and with resist still on the wafer, care needs to be taken to prevent “stop etch” condition during etch-stop etch. This includes preferably adding a step at the beginning of the etch-stop etch to remove polymer from via etch at the bottom of via, or using an etch-stop etch process that is able to remove via etch polymer and etch the etch-stop layer (such as the process described above).

Photoresist 111 is then removed, such as by ashing. The via (wafer) is then cleaned to remove residuals in a via clean step. A trench pattern 115 is then applied, such as using light sensitive photoresist 121 and BARC 122 as shown in FIG. 3(d). A trench is then formed using a highly non-isotropic trench etch through the capping layer 29 and a portion of the low-k dielectric layer 19 to reach a predetermined trench depth, with the resulting structure as shown in FIG. 3(e). Capping layer 29 is retained over top surfaces of the trench. Photoresist 121 and BARC 122 are then removed, such as by ashing. The retained capping layer 29 protects the low-k dielectric film 19, such as a ULK film, particularly at the top surfaces of trench surfaces during trench ash, as well as during the subsequent trench clean step. As can be seen by the resulting damascene stricture in FIG. 3(f) after photoresist 121 and BARC 122 removal, the capping layer 29 is retained over the top surfaces of the trench. As noted above, the capping layer 29 also protects low-k dielectric layer 19 during the subsequent barrier and seed deposition processes, and the first part of the CMP processing.

FIG. 3(g) shows a cross section view of the resulting structure after barrier, seed and metal (e.g. Cu) filling (barrier and seed layer not shown). Note the presence of capping layer 29 beneath the metal 31. FIG. 3(h) shows a cross section view of the resulting structure after CMP processing. In the preferred embodiment shown capping layer 29 is entirely removed by the CMP processing. However, as noted above, although not shown, the CMP process can be designed to leave a portion of the capping layer 29 over low-k dielectric layer 19 in the final device, such as by using a thicker capping layer (e.g. >500 A), or by adjusting the CMP process.

The present invention can be used in a trench-first dual damascene process. As will be appreciated by one having ordinary skill in the art, in the trench process, at least one trench is etched using a trench pattern, wherein the trench is etched through the capping layer, the low-k dielectric layer to reach a predetermined depth, wherein the capping layer is retained over the low-k dielectric layer on the top surfaces of the trench. Following forming a via pattern over the trench, at least one via is etched using the via pattern, the via being etched through the capping layer, low-k dielectric layer, and the etch-stop layer to reach the substrate surface, wherein the capping layer is retained over the low-k dielectric layer on the top surfaces of the trench. As with the via-first process, the via and trench are filled with at least one an electrically conductive material and a CMP process generally performed to form a dual damascene interconnect structure.

The present invention can also be used in a single damascene metal-1 process. As will be appreciated by one having ordinary skill in the art, for a single damascene metal-1 process according to the invention, a substrate surface having an etch-stop layer thereon, a low-k dielectric layer on the etch-stop layer, and a dielectric capping layer on the low-k dielectric layer is provided. A trench pattern is formed using a trench mask and at least one layer of light sensitive material. Using the trench pattern, at least one trench is etched through the capping layer, the low-k dielectric layer and the etch-stop layer to reach the substrate surface, wherein the capping layer is retained over the low-k dielectric layer on the top surfaces of the trench. The resist/BARC strip is then performed. Using conventional processing, the trench is then filled with at least one an electrically conductive material and a CMP process generally performed to form a single damascene interconnect structure.

Compared to other ULK integration schemes or techniques, such as describe above or ULK damage repair through additional E-beam cure steps, the inventive method is significantly easier to implement and also provides better topographical and dimensional control. Broadly, the present invention provides several significant advantages, including:

1. Shorter process time: Retaining the capping layer after trench etch on the surfaces of the trench according to the present invention eliminates one of the three (3) ULK ash steps and one of the three (3) wet clean steps from via etch to trench etch described above in the conventional flow. Specifically the ash step and wet clean step after conventional etch-stop etch are not needed. Moreover, additional ULK damage repair techniques, such as E-beam cure, is not needed since the ULK is spared from significant process-induced damage in the first place.

2. Improved uniformity across wafer in terms of critical dimension (CD) and trench depth. The retained TEOS cap thickness is uniform across wafer (as deposited), which helps trench depth control. Better CD and trench depth control improves control of line-to-line capacitance. In the conventional flow described above, due to etch-stop etch non-uniformity, the TEOS/ULK loss at the top surfaces of trenches is highly non-uniform across the wafer.

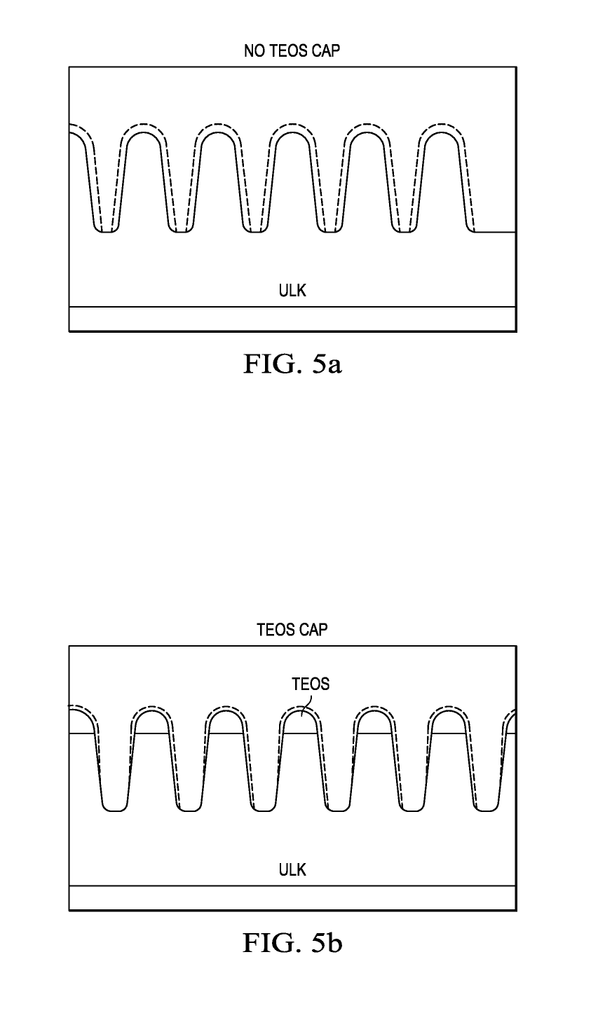

3. Better trench wall profile. In the conventional flow, trench profile bowing often occurs during the etch-stop etch (due to the absence of photoresist). In the inventive flow, etch-stop etch is performed during via etch with resist still on the wafer. See FIGS. 5(a) and (b) described below.

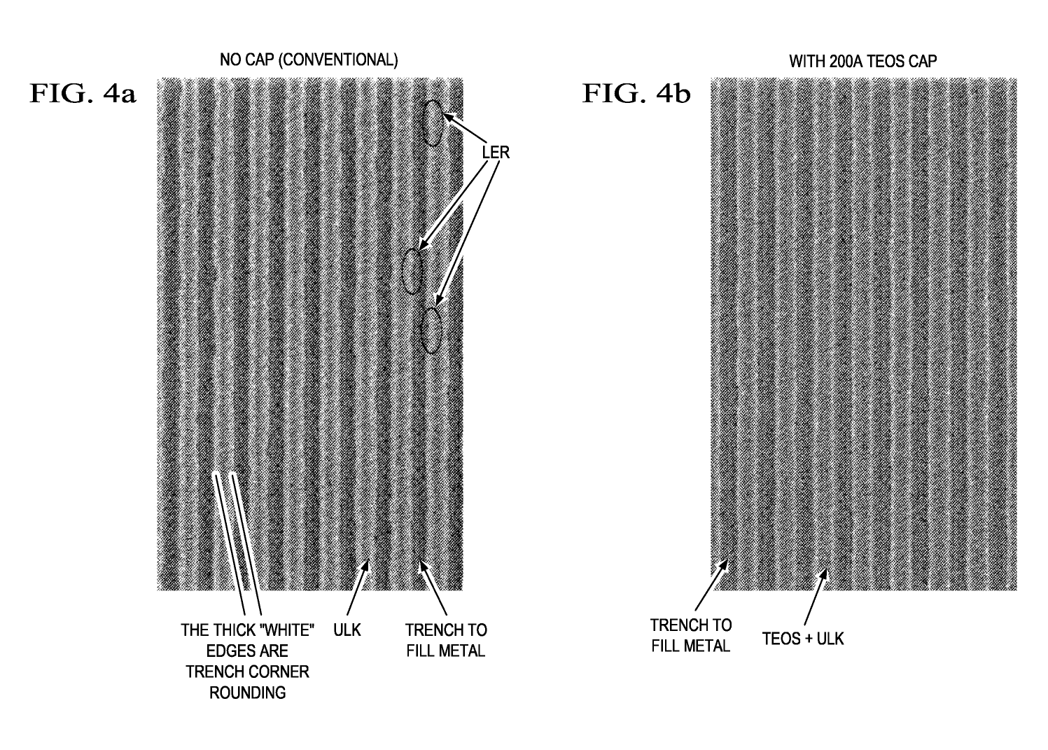

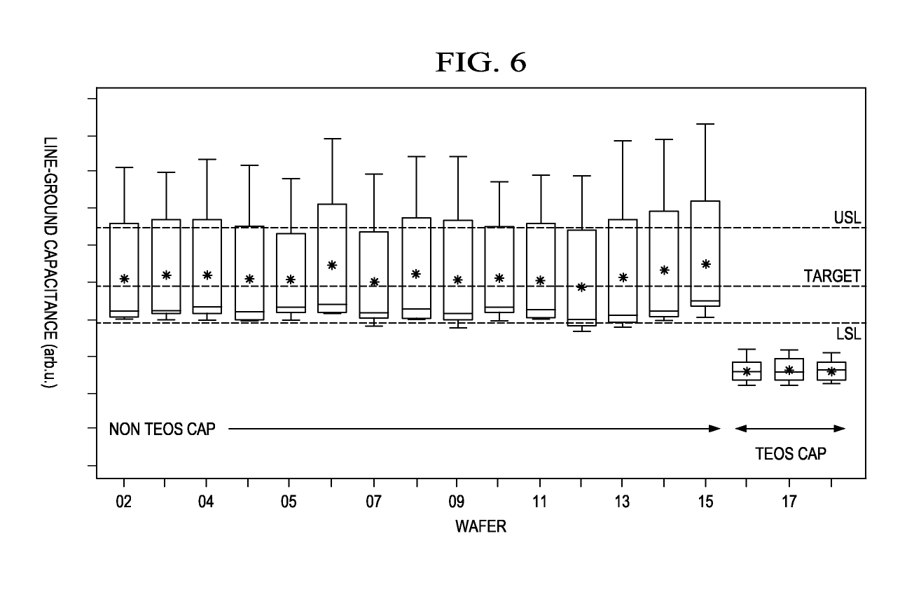

4. Less damage to the ULK. Retaining the capping layer over the top surfaces of the trench though CMP processing significantly reduces low-k damage and trench LER. FIGS. 4(a) and (b) described below evidences a reduction in trench LER. The reduction in ULK damage results in a reduction in both line-to-line and line-to-ground capacitance. The line-line capacitance is primarily affected by CD, slope and ULK damage, whereas the line-ground capacitance is primarily affected by trench depth and ULK damage. FIG. 6 described below provides data evidences the improvement in line-to-ground capacitance. Moreover, the presence of a capping layer over the trench through CMP processing provided by the present invention also helps prevent low-k damage and trench corner rounding from occurring during the barrier/seed deposition and CMP process.

As well known in the art, the post-etch topography of the low-k film in damascene processes are very important to metallization. The low-k film must provide adhesion of the copper (or other metal) barrier. If the trench and via sidewalls are smooth and continuous, with essentially no breaks or inverted slopes, copper barrier deposition has a large process margin. Imperfections, such as microtrenching can pose problems for electro-chemical deposition, creating discontinuities that pose the risk of copper (or other metal) diffusion into ULK film and, ultimately, device failure.

FIG. 4(a) is a SEM image showing topography achieved using a conventional via-first dual damascene process (ULK without a capping layer), while FIG. 4(b) is a SEM image showing topography achieved using a via-first dual damascene process according to the present invention (ULK with a 200 A TEOS capping layer). Theses images were both taken after trench-2 etch clean (that is, right before metal-2 barrier/seed deposition). The thick white edges in FIG. 4(a) evidence a high degree of undesirable trench corner rounding (or erosion). The white edges in FIG. 4(b) are significantly thinner. In addition, the trench line-edge-roughness (LER) evidencing mouse bites is also seen to be much more severe in the image shown in FIG. 4(a) as compared to the trench LER in the image based on dual damascene processing according to the present invention shown in FIG. 4(b). Moreover, although not shown in FIGS. 4(a) and (b) due to the images being taken right before metal-2 barrier/seed deposition, as noted above, following the barrier/seed deposition process the trench corner rounding has been found to worsen considerably without the presence of a capping layer on the top surf aces of the trench according to the present invention.

FIGS. 5(a) and (b) show traced contour representations of SEM-derived trench cross-section images for a conventional TEOS cap removal process after the trench etch process (which removes the entire capping layer) as compared to a trench process according to the invention where the TEOS (or other) capping layer is retained on the top surfaces of the trench at least through CMP processing, respectively. The as-deposited thickness of the capping layer used for the trench process according to the invention was about 200 A (as is the thickness of the capping layer shown in FIG. 5(b)). The solid line in each representation is derived from a SEM taken after trench etch, and the dashed line is derived from a SEM of the same structure following a dilute HF (50:1 or 100:1) dip for 20 to 30 sections which quickly and preferentially removes the process damaged ULK. Comparing FIG. 5(b) to FIG. 5(a) clearly evidences the trench process according to the present invention (which retains the TEOS cap over the top surfaces of the trench) reduces the damage region of the underlying ULK by over 75% as compared to the conventional trench process (which removes the TEOS cap completely). The trench process according to the present invention is also seen to significantly improve trench topography.

As noted above, a significant advantage of using the TEOS cap according to the present invention is better within wafer (center to edge) uniformity. In other words trench lines in the center and edge die of a wafer have been found to be very similar. The trench depths are also very similar. As a result, the electrical parameters, such as resistance and capacitance become more uniform across a die and across a wafer. FIG. 6 shows a plot of line-to-ground capacitance for capacitors formed using the conventional process via process described above (indicated as “Non TEOS Cap”, wafers number 1-15) which removes the TEOS capping layer at etch-stop etch, as compared to capacitors formed using the process according to the invention which retains the capping layer (e.g. TEOS) through at least CMP processing (indicated as “TEOS cap”, wafers number 16-18). The trench pitch was about 140 nm. The line to ground capacitance parameter (arbitrary units) is seen to significantly improve using the invention in both absolute capacitance value (30 to 42 for the known process vs. about 25 for the process according to the invention), and is also seen to be far more uniform.

Various modifications to the invention as described above are within the scope of the claimed invention. As an example, as noted above, the present invention may be used on one or every dual damascene layer of the BEOL structure 5, as well as on a single damascene metal-1 process, such as for metal layer 12. In addition, it is within the scope of the invention to have a BEOL structure 5 with a different amount or configuration of metal layers 12, 13, 22 than is shown in FIGS. 1 and 2. Moreover, the dual damascene layers 13, 22 may be fabricated with either the via-first (described above) or a trench-first process. In the trench first process, the etch-stop layer is etched during via etch to allow retaining the capping layer.

The interconnect structures 12, 13, 22 may contain more layers, such as a thin capping layer (e.g. TEOS) between the dielectric layers 17, 19 and their respective adjoining etch-stop layers 20 and 21. Furthermore, although not shown above, dielectric layer 17 and 19 can include a trench etch-stop layer therein as known in the art. Furthermore, the semiconductor substrate 3 may include various elements therein and/or layers thereon. These can include metal layers, barrier layers, dielectric layers, device structures, active elements and passive elements including word lines, source regions, drain regions, bit lines, bases, emitters, collectors, conductive lines, conductive vias, etc. Moreover, instead of using the invention on a CMOS structure as described above, the invention is applicable to other semiconductor technologies such as BiCMOS, bipolar, SOI, strained silicon, pyroelectric sensors, opto-electronic devices, microelectrical mechanical system (MEMS), or SiGe.

While various embodiments of the present invention have been described above, it should be understood that they have been presented by way of example only, and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

We claim:

1. A method of forming dual damascene interconnect structures, comprising the steps of:
providing a substrate surface, and forming an etch-stop layer thereon, a low-k dielectric layer on said etch-stop layer, and a dielectric capping layer on said low-k dielectric layer;
forming a via pattern using a via mask and at least one layer of light sensitive material;
etching at least one via using said via pattern, said via being etched through said capping layer, said low-k dielectric layer and said etch-stop layer to reach said substrate surface;
forming a trench pattern over said via using a trench mask and said layer of light sensitive material;
etching at least one trench using said trench pattern, wherein said trench is etched through said capping layer and a portion of said low-k dielectric layer to reach a predetermined depth, wherein said capping layer is retained over said low-k dielectric layer on top surfaces of said trench, and
filling said trench and said via with at least one an electrically conductive material to form a dual damascene interconnect structure.

2. The method of claim 1, wherein said capping layer comprises TEOS, silicon carbide, silicon nitride, silicon oxy-nitride or their combination.

3. The method of claim 1, wherein a thickness of said capping layer is between 100 and 500 A.

4. The method of claim 1, wherein said filling step comprises the steps of:
depositing a barrier layer to line said via and said trench;
depositing a seed layer on said barrier layer, and
depositing a Cu comprising metal on said seed layer.

5. The method of claim 4, further comprising the step of chemical mechanical polishing (CMP), wherein said CMP step removes all of said capping layer.

6. The method of claim 1, wherein said etch-stop layer comprises SiCN, SiCO/SiCN, Si₃N₄ or SiCO/Si₃N₄.

7. The method of claim 1, wherein said low-k dielectric layer is deposited as a CVD film or a spin-on film.

8. The method of claim 1, further comprising the steps of:
providing a semiconductor substrate, and
prior to forming said dual damascene interconnect structure, forming at least one MOS transistor in and on said substrate, said MOS transistor comprising a source and drain having a channel region interposed between, and a gate electrode and a gate insulator over said channel region, a layer of dielectric insulation including at least one metal contact electrically coupled to said transistor;
wherein said dual damascene interconnect structure is electrically coupled to said metal contact.

9. A method of forming dual damascene interconnect structures, comprising the steps of:
providing a substrate surface having an etch-stop layer thereon, a low-k dielectric layer on said etch-stop layer, and a dielectric capping layer on said low-k dielectric layer;
forming a trench pattern using a trench mask and at least one layer of light sensitive material;
etching at least one trench using said trench pattern, said trench being etched through said capping layer and a portion of said low-k dielectric layer to reach a predetermined trench depth, wherein said capping layer is retained over said low-k dielectric layer on top surfaces of said trench;
providing a via pattern over said trench using a via mask and at least one layer of said light sensitive material,
etching at least one via using said via pattern, wherein said via is etched through said capping layer and said low-k dielectric layer and said etch-stop layer to reach said substrate surface, wherein said capping layer is retained over said low-k dielectric layer on said top surfaces of said trench, and
filling said via and said trench with at least one electrically conductive material to form a dual damascene interconnect structure.

10. The method of claim 9, wherein said capping layer comprises TEOS, silicon carbide, silicon nitride, silicon oxy-nitride or their combination.

11. The method of claim 9, wherein a thickness of said capping layer is between 100 and 500 A.

12. The method of claim 9, wherein said filling step comprises the steps of:
depositing a barrier layer to line said via and said trench;
depositing a seed layer on said barrier layer, and
depositing a Cu comprising metal on said seed layer

13. The method of claim 12, further the comprising step of chemical mechanical polishing (CMP), wherein said CMP step removes all of said capping layer.

14. The method of claim 9, wherein said etch-stop layer comprises SiCN, SiCO/SiCN, Si₃N₄ or SiCO/Si₃N₄.

15. The method of claim 9, wherein said low-k dielectric layer is deposited as a CVD film or a spin-on film.

16. The method of claim 1, further comprising the steps of:
providing a semiconductor substrate, and
prior to forming said dual damascene interconnect structure, forming at least one MOS transistor in and on said substrate, said MOS transistor comprising a source and drain having a channel region interposed between, and a gate electrode and a gate insulator over said channel region, a layer of dielectric insulation including at least one metal contact electrically coupled to said transistor;
wherein said dual damascene interconnect structure is electrically coupled to said metal contact.

17. A method of forming single damascene interconnect structures, comprising the steps of:
providing a substrate surface having an etch-stop layer thereon, a low-k dielectric layer on said etch-stop layer, and a dielectric capping layer on said low-k dielectric layer;
forming a trench pattern using a trench mask and at least one layer of light sensitive material;
etching at least one trench using said trench pattern, said trench being etched through said capping layer, said low-k dielectric layer and said etch-stop layer to reach said substrate surface, wherein said capping layer is retained over said low-k dielectric layer on top surfaces of said trench, and
filling said trench with at least one electrically conductive material to form a single damascene interconnect structure.

18. The method of claim 17, wherein said capping layer comprises TEOS, silicon carbide, silicon nitride, silicon oxy-nitride or their combination.

19. The method of claim 17, wherein a thickness of said capping layer is between 100 and 500 A.

20. The method of claim 17, wherein said filling step comprises the steps of:
depositing a barrier layer to line said trench;
depositing a seed layer on said barrier layer, and
depositing a Cu comprising metal on said seed layer

21. The method of claim 20, further comprising the step of chemical mechanical polishing (CMP), wherein said CMP step removes all of said capping layer.

22. The method of claim 17, wherein said etch-stop layer comprises SiCN, SiCO/SiCN, Si₃N₄ or SiCO/Si₃N₄.

23. The method of claim 17, wherein said low-k dielectric layer is deposited as a CVD film or a spin-on film.

24. The method of claim 17, further comprising the steps of:
providing a semiconductor substrate, and
prior to forming said single damascene interconnect structure, forming at least one MOS transistor in and on said substrate, said MOS transistor comprising a source and drain having a channel region interposed between, and a gate electrode and a gate insulator over said channel region, a layer of dielectric insulation including at least one metal contact electrically coupled to said transistor;
wherein said single damascene interconnect structure is electrically coupled to said metal contact.

25. A method of forming dual damascene interconnect structures, comprising the steps of:
providing a substrate surface having an etch-stop layer thereon, a low-k dielectric layer on said etch-stop layer, and a dielectric capping layer on said low-k dielectric layer, wherein said capping layer comprises TEOS and a thickness of said TEOS is between 100 and 250 A;
forming a via pattern using a via mask and at least one layer of light sensitive material;
etching at least one via using said via pattern, said via being etched through said capping layer, said low-k dielectric layer and said etch-stop layer to reach said substrate surface;
providing a trench pattern over said via using a trench mask and at least one layer of said light sensitive material,
etching at least one trench using said trench pattern, wherein said trench is etched through said capping layer and a portion of said low-k dielectric layer to reach a predetermined depth, wherein said capping layer is retained over said low-k dielectric layer on top surfaces of said trench;
depositing a barrier layer to line said via and said trench;
depositing a seed layer on said barrier layer, and
filling said trench and said via with a Cu comprising metal on said seed layer, and
performing chemical mechanical polishing (CMP) to form a dual damascene interconnect structure, wherein said CMP removes all of said capping layer.
